(19) United States
(12) Patent Application Publication
(10) Pub. No.: US 2026/0182102 A1
(43) Pub. Date: Jun. 25, 2026

(54) LED LIGHT-EMITTING DEVICE AND METHOD FOR MANUFACTURING THE SAME

(71) Applicant: HUIZHOU JUFEI OPTOELECTRONICS LTD., Huizhou, Guangdong (CN)

(72) Inventors: Dongdong WANG, Huizhou (CN); Limin YANG, Huizhou (CN); Pingru SUN, Huizhou (CN); Chuanhu WANG, Huizhou (CN); Panfeng TAN, Huizhou (CN); Chunliang LI, Huizhou (CN); Hui HUANG, Huizhou (CN); Pianpian WU, Huizhou (CN)

(73) Assignee: HUIZHOU JUFEI OPTOELECTRONICS LTD., Huizhou, Guangdong (CN)

(21) Appl. No.: 19/125,646

(22) PCT Filed: Nov. 3, 2023
(86) PCT No.: PCT/CN2023/129764

§ 371 Date: Apr. 29, 2025

(30) Foreign Application Priority Data
Nov. 4, 2022 (CN) 202211377346.4

(51) Int. Cl. H10H 20/854; H10H 20/01; H10H 20/85; H10H 20/853

(52) U.S. Cl. CPC H10H 20/854; H10H 20/0362; H10H 20/8502; H10H 20/8508; H10H 20/853

(57) ABSTRACT

The present disclosure is applicable to the field of LED packaging technology and provides an LED light-emitting device and a method for manufacturing the same. The LED light-emitting device comprises a support, an LED chip, and an encapsulant layer. The support comprises a substrate and a dam part. The substrate has opposite front and back surfaces, and the dam part has opposite bottom and top surfaces. The LED chip and the bottom surface of the dam part are disposed on the front surface of the substrate. The dam part surrounds the LED chip, forming a chip mounting area for installing the LED chip and carrying the encapsulant layer. The encapsulant layer is encapsulated above the LED chip. The dam part and the encapsulant layer are transparent or translucent, and the top of the encapsulant layer is provided with transparent or translucent hollow particles. The LED light-emitting device and method for manufacturing the same provided by the present disclosure offer high brightness and excellent user experience.

### TECHNICAL FIELD

The present disclosure belongs to the field of LED packaging technology, and particularly relates to an LED light-emitting device and a method for manufacturing the same.

### BACKGROUND

With the rapid development of liquid crystal display technology in recent years, there is a trend towards larger screens. Driven by the demand for high dynamic range (HDR) and the “home economy”, Mini LED display technology is gradually penetrating the medium and large-sized application fields, including TVs, commercial displays, and gaming. Currently, the mainstream Mini backlight technology is blue LED combined with quantum dot film, using dispensing or white adhesive spraying coating technology on the surface of the lamp bead (e.g., CN112186090A). Although this solution achieves a light-emitting angle of 160°, the light-blocking layer (white glue) significantly obstructs light, resulting in a substantial sacrifice of the central light intensity of the LED lamp bead, leading to severely low luminous flux of the lamp bead, insufficient product brightness, and subpar user experience.

In existing technologies, there are also solutions using transparent supports, such as the display device and its four-sided light-emitting LED disclosed in CN107086263B. This solution uses a four-sided light-emitting approach, where the transparent support is formed on the substrate through thermoplastic molding. The transparent support is generally made of transparent plastic, such as PPA (polyphthalamide), PCT (Poly1,4-cyclohexylene dimethylene terephthalate), or thermoplastic resin. However, its light transmittance is insufficient, affecting the side light intensity, and the top light intensity is significantly lost due to the reflective white glue layer, resulting in a subpar actual user experience.

### SUMMARY

An object of the present disclosure is to overcome the shortcomings of the existing technologies mentioned above by providing an LED light-emitting device and a method for manufacturing the same, which can reduce the light intensity loss at the top of the LED light-emitting device, thereby improving the brightness of the LED light-emitting device and achieving a better user experience.

The technical solution of the present disclosure is as follows: an LED light-emitting device includes a support, an LED chip, and an encapsulant layer, wherein the support includes a substrate having opposite front and back surfaces and a dam part having opposite bottom and top surfaces, wherein the LED chip and a bottom surface of the dam part are disposed on a front surface of the substrate, the dam part surrounds the LED chip, forming a chip mounting area for installing the LED chip and carrying the encapsulant layer, the encapsulant layer is encapsulated above the LED chip; and the dam part and the encapsulant layer are transparent or translucent, and a top of the encapsulant layer is provided with transparent or translucent hollow particles; and a height of the dam part is a distance from the front surface of the substrate to the top surface of the dam part, and a height of the encapsulant layer protruding from the support is a distance from the top surface of the dam part to the top of the encapsulant layer, wherein the height of the encapsulant layer protruding from the support is greater than the height of the dam part.

Optionally, an outer surface of the encapsulant layer is curved and has a shape that is larger at the bottom and smaller at the top; and the top of the encapsulant layer is located directly above the chip mounting area, and the hollow particles cover an area directly above the LED light-emitting device.

Optionally, at least part of the encapsulant layer is not covered by the hollow particles, and the hollow particles at least cover an area directly above the LED chip.

Optionally, a projection area of the hollow particles on a bottom surface of the encapsulant layer accounts for 20%-80% of a bottom surface area of the encapsulant layer; or a thickness of the encapsulant layer surface not covered by the hollow particles is at least greater than the height of the dam part.

Optionally, the encapsulant layer includes a first encapsulant layer and a second encapsulant layer, wherein the bottom of the first encapsulant layer is encapsulated on the front surface of the substrate, and the bottom of the second encapsulant layer is encapsulated on the top of the first encapsulant layer; and the first encapsulant layer contains phosphor, and most of the phosphor is located at the bottom of the first encapsulant layer; and a top surface of the first encapsulant layer is lower than the top surface of the dam part.

Optionally, a mass content of the hollow particles in the second encapsulant layer is 1%-5%.

Optionally, a median particle size of the hollow particles is 15 μm-100 μm.

Optionally, wherein the top surface of the dam part is inclined toward an inner side of the dam part.

The present disclosure further provides a method for manufacturing an LED light-emitting device for manufacturing the LED light-emitting device as described above, including the following steps of:
preparing a support and providing an encapsulant layer with hollow particles on the support; and
allowing a height of the encapsulant layer protruding from the support greater than a height of the support.

Optionally, the step of providing an encapsulant layer includes the following steps:
after providing a first encapsulant containing phosphor within the dam part, settling the phosphor by a centrifugal process to, and curing or semi-curing the first encapsulant by a quick-bake process; and
providing a second encapsulant mixed with hollow particles above the first encapsulant, and baking to allow the hollow particles to aggregate at the top of the second encapsulant to form a hollow particle aggregation area.

According to the LED light-emitting device and a method for manufacturing the same provided by the present disclosure, due to the low density and lightweight characteristics of the hollow particles, they can aggregate in the upper region of the encapsulant after heating. The hollow particles are white particles with reflective and refractive properties, causing the light directly above the lamp bead to undergo secondary mixing through reflection and refraction by the hollow particles, thereby refracting/reflecting the central light intensity of the lamp bead to the sides to enhance the light intensity on both sides of the lamp bead. Moreover, due to the hollow structure of the hollow particles, light transmission is increased, thus improving the light-emitting angle without significantly reducing the overall brightness of the lamp bead. Additionally, since the hollow particles can be suspended above the LED chip and are separated from the phosphor encapsulant by a distance (the colloid of the second encapsulating layer separates the phosphor encapsulant and the hollow particles), most of the light can be emitted from the colloid between the hollow particles and the phosphor encapsulant, relatively enhancing the light intensity on both sides. When applied to the backlight panel of a display screen, it can increase the pitch of the lamp beads on the panel, reduce the number of lamp beads on the same panel, lower the cost of the lamp beads, and provide excellent brightness and user experience for the display product at a low application cost.

### BRIEF DESCRIPTION OF DRAWINGS

To more clearly illustrate the technical solutions in the embodiments of the present disclosure, the following will briefly introduce the drawings needed in the embodiments. Obviously, the drawings in the following description are only some embodiments of the present disclosure. For those of ordinary skill in the art, other drawings can be obtained from these drawings without creative effort.

FIG. 1 is a cross-sectional schematic diagram of a support in an LED light-emitting device provided by an embodiment of the present disclosure.

FIG. 2a is a cross-sectional schematic diagram of a support and a first encapsulating layer in an LED light-emitting device provided by an embodiment of the present disclosure.

FIG. 2b is a cross-sectional schematic diagram of a support and a first encapsulating layer in another LED light-emitting device provided by an embodiment of the present disclosure.

FIGS. 3a, 3b, and 3c are cross-sectional schematic diagrams of the A-A section in FIG. 5a or FIG. 5b.

FIG. 4 is a schematic diagram of the proportion of the bottom area of the encapsulating layer occupied by hollow particles in an LED light-emitting device provided by an embodiment of the present disclosure, viewed from a top angle.

FIG. 5a is a top-view structural schematic diagram of an LED light-emitting device provided by an embodiment of the present disclosure.

FIG. 5b is a top-view structural schematic diagram of another LED light-emitting device provided by an embodiment of the present disclosure.

FIG. 6a is a light effect schematic diagram of FIG. 3a.

FIG. 6b is a light effect schematic diagram of FIG. 3b.

FIG. 7 is a light effect schematic diagram of the prior art.

FIG. 8 is a light intensity distribution schematic diagram of the LED light-emitting device shown in FIG. 6b.

FIG. 9 is a light intensity distribution schematic diagram of an LED light-emitting device with a white colloid covering the top surface in the prior art.

FIG. 10 is a cross-sectional structural schematic diagram of an LED light-emitting device in another embodiment.

FIG. 11 is a top view structural schematic diagram of an LED light-emitting device applied to the backlight panel in an embodiment of the present disclosure;

FIG. 12 is a schematic diagram of the light effect of an LED light-emitting device applied to the backlight panel in an embodiment of the present disclosure;

FIG. 13 is a schematic diagram of the cross-sectional structure and light effect of an LED light-emitting device in another embodiment;

FIG. 14 is a schematic diagram of the cross-sectional structure and light effect of an LED light-emitting device in another embodiment;

FIG. 15 is a schematic diagram of the cross-sectional structure of an LED light-emitting device in another embodiment.

### DESCRIPTION OF EMBODIMENTS

In order to make the objectives, technical solutions, and advantages of the present disclosure clearer, the following will provide a further detailed description of the present disclosure in conjunction with the accompanying drawings and embodiments. It should be appreciated that the specific embodiments described herein are merely intended to explain the present disclosure and are not intended to limit the present disclosure.

It should be noted that when an element is referred to as being “fixed to” or “disposed on” another element, it can be directly on the other element or there may be an intervening element. When an element is referred to as being “connected to” another element, it can be directly connected to the other element or there may be an intervening element.

Additionally, in the embodiments of the present disclosure, terms indicating orientation or positional relationships such as “longitudinal,” “transverse,” “length,” “width,” “thickness,” “upper,” “lower,” “front,” “rear,” “left,” “right,” “vertical,” “horizontal,” “top,” “bottom,” “inner,” and “outer” are based on the orientation or positional relationships shown in the accompanying drawings or the conventional placement or usage state. They are used merely to facilitate the description of the present disclosure and to simplify the description, rather than to indicate or imply that the referred structures, features, devices, or elements must have a specific orientation or positional relationship, nor must they be constructed and operated in a specific orientation. Therefore, they should not be construed as limitations on the present disclosure. In the description of the present disclosure, unless otherwise specified, the term “a plurality of” means two or more.

The various specific technical features and embodiments described in the detailed description can be combined in any suitable manner without contradiction. For example, different implementation methods can be formed by combining different specific technical features/embodiments. To avoid unnecessary repetition, various possible combinations of specific technical features/embodiments in the present disclosure will not be further described.

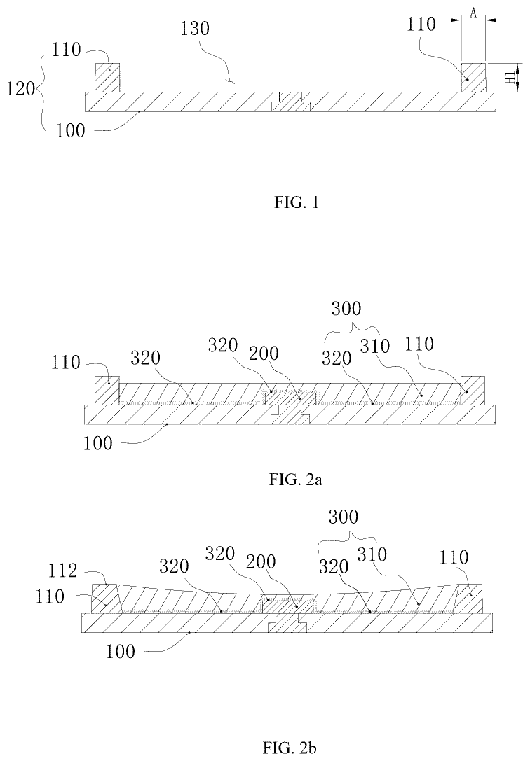

As shown in FIGS. 1, 2a, 2b, 3a, 3b, and 3c, an embodiment of the present disclosure provides an LED light-emitting device (lamp bead) 10, which includes a support 120, an LED chip 200, and an encapsulant layer 400. The support 120 includes a substrate 100 and a dam part 110. The substrate 100 can be a metal substrate, a ceramic substrate with a metal coating, a glass substrate, or other substrates with conductive properties. The substrate 100 has opposite front and back surfaces, and the dam part 110 has opposite bottom and top surfaces. The LED chip 200 and the dam part 110 are disposed on the front surface of the substrate 100, with the dam part 110 surrounding the LED chip 200 to form a chip mounting area 130 for installing the LED chip and carrying the encapsulant. Depending on different applications and light efficiency requirements, the shape of the chip mounting area 130 can vary, such as the rectangular shape shown in FIG. 5a, the circular shape shown in FIG. 5b, or other shapes, with no restrictions on the shape of the chip mounting area 130 in this application. The encapsulant layer 400 is encapsulated above the LED chip 200, and both the dam part 110 and the encapsulant layer 400 are transparent or semi-transparent. The entire side surface of the LED light-emitting device (including the dam part 110) can emit light, with enhanced light effects on the side surfaces. The material of the encapsulant layer 400 can be epoxy resin, silicone resin, or other resins with strong light transmittance. The dam part 110 can be made of transparent materials, including but not limited to EKE091, PPA, PCT, etc. The top of the encapsulant layer 400 is provided with transparent or semi-transparent hollow particles. In this embodiment, the hollow particles are glass microspheres with a hollow center, chemically similar to soda-lime borosilicate glass compositions, exhibiting excellent water resistance, non-flammability, and non-porosity, so the hollow particles do not absorb the resin (encapsulant) and can be compatible with the resin, resulting in low application costs. Additionally, due to the low density and lightweight characteristics of the hollow particles, they can aggregate in the upper region of the encapsulant layer 200 through heating and can be suspended above the LED chip 200. The hollow particles are transparent particles, with reflective and refractive properties, allowing the light directly above the lamp bead to be reflected and refracted by the hollow particles (since the hollow particles are transparent or semi-transparent hollow structures with small particle sizes, they have the characteristic of refracting and reflecting light, appearing white visually) to the side regions, thereby enhancing the light intensity on both sides of the lamp bead.

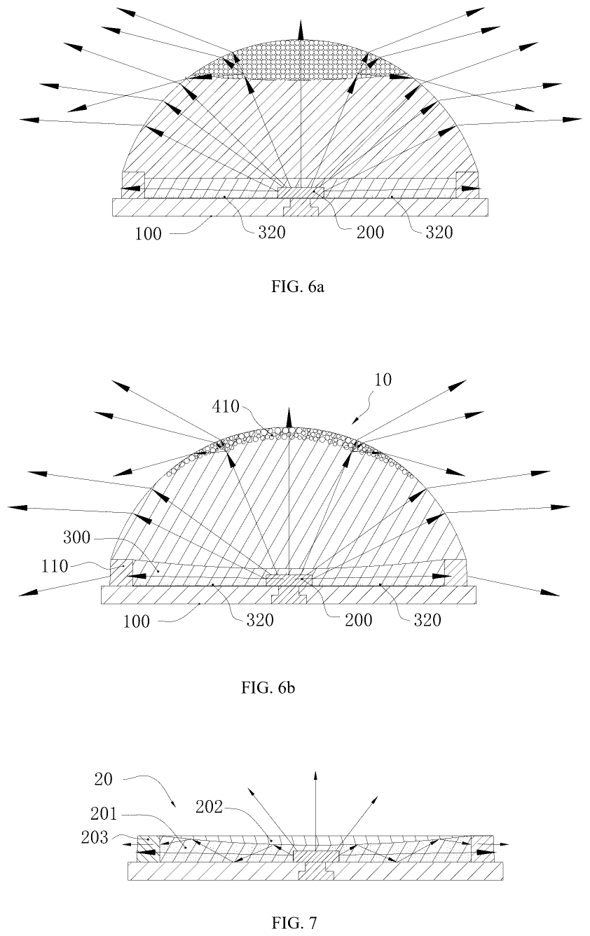

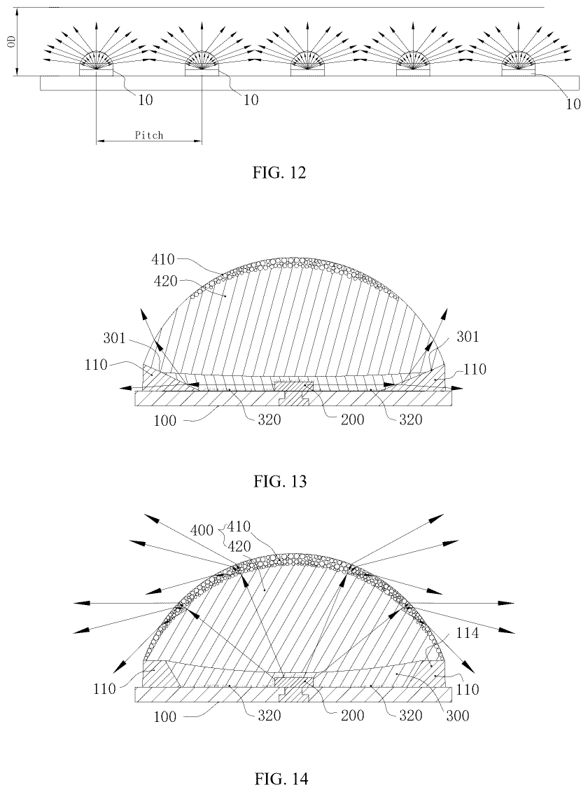

The height H1 of the dam 120 is the distance from the front surface of the substrate 100 to the top surface of the dam part 110. The height H2 of the encapsulant layer 400 protruding from the dam 120 is the distance from the top surface of the dam part 110 to the top of the encapsulant layer 400. The height of the encapsulant layer 400 protruding from the dam 120 is greater than the height of the dam 120, i.e., H2 is greater than H1 (preferably H2 is 1 to 2 times H1), increasing the proportion of the height of the encapsulant layer 400 protruding from the dam 120 in the total height of the LED light-emitting device, causing the hollow particles to concentrate at the top of the encapsulant layer 400 and near the top of the LED chip 200, reflecting the light emitted from the top surface of the LED chip 200. The encapsulant layer 400 protruding from the dam 120 helps the hollow particles to be distributed in a higher area (refer to FIGS. 6a, 6b, and 14), reducing the obstruction of the light reflected and refracted by the hollow particles, making it easier to reflect and refract the light to the sides of the LED light-emitting device, reducing the obstruction of the light emitted by the LED chip by the dam. With the hollow particles set at the top of the encapsulant layer 400, the light output from the top of the LED light-emitting device is appropriately weakened, and the light output from the sides is increased. At the same time, referring to FIG. 6b, the dam part 110 is transparent, therefore the light emitted by the LED chip can pass through the dam part 110 to the periphery of the LED light-emitting device 10, and the light reflected and refracted by the hollow particles is superimposed, enhancing the light at the periphery of the LED light-emitting device 10 and improving the uniformity of light output. Referring to FIGS. 11 and 12, the LED light-emitting device 10 can be disposed in an array on a PCB board to form a backlight panel applied to a display screen, making the light intensity of the backlight panel uniform, increasing the pitch of the lamp beads on the panel, reducing the number of lamp beads on the same panel, lowering the cost of the lamp beads, and improving the brightness and experience of the display screen product.

Specifically, the outer surface of the encapsulant layer 400 is curved and has a shape that is larger at the bottom and smaller at the top. The top of the encapsulant layer 400 is directly above the chip mounting area 130, and the hollow particles cover the area directly above the LED chip 200, forming a hollow particle aggregation area 410 at the top of the encapsulant layer 400. In some embodiments, the encapsulant layer 400 may be dome-shaped, with the LED chip 200 located at the bottom center or near the center of the encapsulant layer. The LED light-emitting device has good light output uniformity and excellent performance.

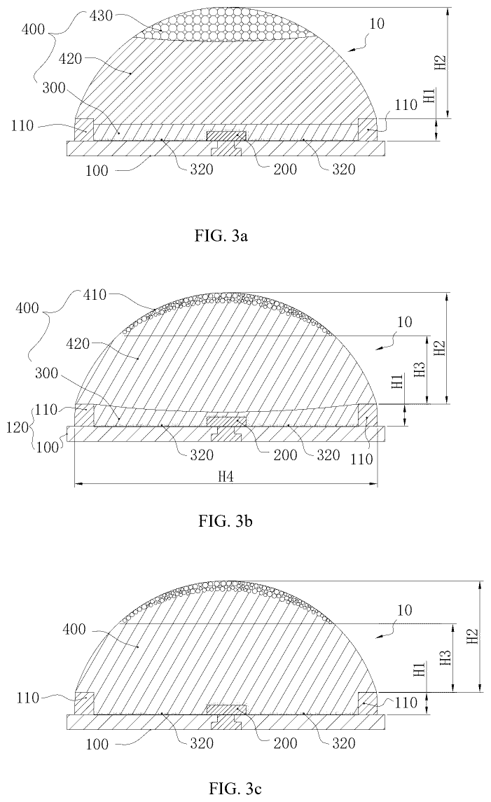

As shown in FIG. 1, FIG. 3a, FIG. 3b, and FIG. 3c, the encapsulant layer 400 at least covers the inner side and top of the dam part 110, and at least fills the chip mounting area 130, thereby minimizing the obstruction of light emitted from the surface of the encapsulant layer 400 by the dam part 110, and enhancing the side light intensity of the LED light-emitting device. Since the encapsulant layer 400 can be formed through a dispensing process during production, and if the protrusion height of the encapsulant layer 400 is too high, it may overflow outside the dam part 110 due to its own gravity. In a preferred embodiment, the height H2 of the encapsulant layer 400 is lower than the length H4 and/or width H5 of the dam part 110 (refer to FIGS. 5a and 5b), to reduce the occurrence of adhesive overflow during the production process.

In specific applications, referring to FIGS. 5a and 5b (the shaded area in the FIG. represents the area occupied by the dam part 110), the dam part 110 can be fixedly or integrally set on the front side of the substrate 100, and the shapes of the dam part 110 and the chip mounting area 130 can be flexibly set, which is not limited in this application. As shown in the top view of an LED light-emitting device in FIG. 5a, the outer contour of the dam part 110 is square, and the chip mounting area 130 is also square; as shown in the top view of another LED light-emitting device in FIG. 5b, the outer contour of the dam part 110 is square, and the chip mounting area 130 is circular. In other embodiments, in this embodiment, there is one LED chip 200 set inside the chip mounting area 130, and the LED chip 200 is located at the center of the chip mounting area 130. In other embodiments, two or more LED chips 200 can be set, and the chip mounting area 130 can also be used for installing protective components, such as Zener diodes, in addition to chips.

In specific applications, the encapsulant layer 400 can be a single-layer structure depending on the production process, for example, the encapsulant layer 400 shown in FIG. 3c is a single-layer structure, and hollow particles can be located at the top of the single-layer encapsulation adhesive; the encapsulant layer 400 can also be a 2-layer structure (hollow particles can be located at the top of the uppermost encapsulant layer), for example, the encapsulant layer 400 shown in FIG. 3b includes a first encapsulant layer 300 at the bottom and a second encapsulant layer 420 at the top, and hollow particles can be located at the top of the second encapsulant layer 420; the encapsulant layer 400 can also be a 3-layer or more structure, for example, the encapsulant layer 400 shown in FIG. 3a includes a first encapsulant layer 300 at the bottom, a second encapsulant layer 420 in the middle, and a third encapsulant layer 430 at the top; hollow particles can be located at the top of the third encapsulant layer 430. The number of layers of the encapsulant layer 400 is not limited in this application.

In one embodiment, as shown in FIG. 14, the hollow particle aggregation area 410 can completely cover the encapsulant layer 400 (since there will be gaps between the hollow particles, the term “completely cover” here means that it appears to be mostly covered visually, with no obvious blank areas); in another embodiment, as shown in FIGS. 6a and 6b, the hollow particles may not completely cover the encapsulant layer 400, meaning that at least part of the encapsulant layer 400 is not covered by the hollow particles. The choice can be made based on the desired light effect for the product design, and this application does not impose any restrictions.

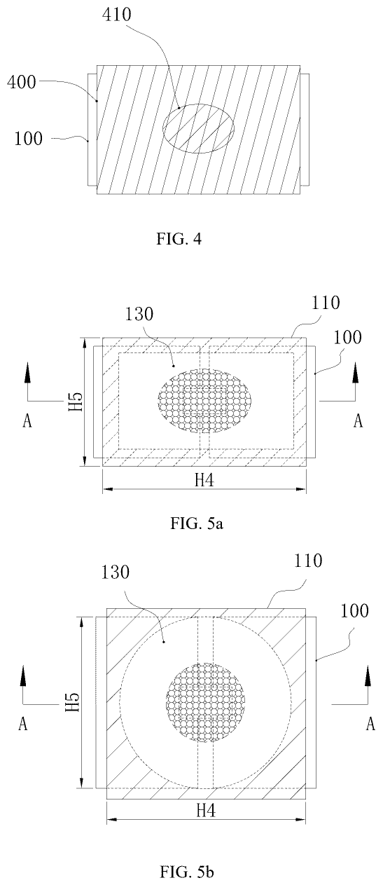

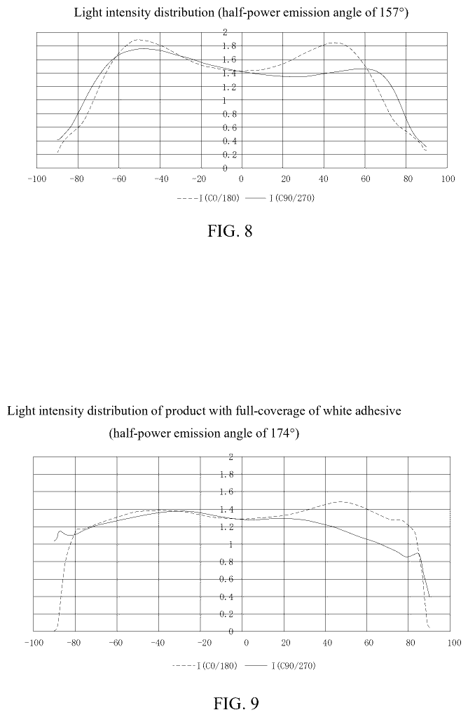

In specific applications, referring to FIGS. 3a, 3b, 3c, 4, and 6b, in one embodiment, the projection area of the hollow particle aggregation area 410 on the bottom surface of the encapsulant layer 400 accounts for 20%-80% of the bottom surface area of the encapsulant layer 400, preferably 24%-40%, which allows the middle light intensity of the lamp bead to be appropriately shifted to the sides to enhance the light intensity on both sides of the lamp bead. Additionally, the hollow particle aggregation area 410 does not completely cover the upper surface of the encapsulant layer 400, which can reduce the blocking of light emitted sideways by the LED, thereby enhancing the lateral light of the LED (refer to FIG. 8 for the light intensity distribution).

In another embodiment, the thickness H3 of the encapsulant layer 400 that is not covered by hollow particles is at least greater than the height of the dam part H1. This ensures that a sufficient amount of light is directly refracted from the encapsulant layer 400, and when combined with the light reflected and refracted by the hollow particles, the lateral light of the LED is enhanced (refer to FIG. 8 for the light intensity distribution).

Specifically, referring to the embodiments shown in FIGS. 3b and 6b, the encapsulant layer 400 includes a first encapsulant layer 300 and a second encapsulant layer 420. The bottom of the first encapsulant layer 300 is encapsulated on the front side of the substrate 100, and the bottom of the second encapsulant layer 420 is encapsulated on the top of the first encapsulant layer 300. The first encapsulant layer 300 contains phosphor, which can be used to convert the wavelength of the light emitted by the LED chip to produce white light or other desired light. Most of the phosphor is located at the bottom of the first encapsulant layer 300, meaning that the dam part 110 contains the first encapsulant layer 300 with phosphor, and the first encapsulant layer 300 can be a phosphor adhesive (containing phosphor).

As shown in FIGS. 2a and 2b, the first encapsulant layer 300 may not protrude from the dam part 110, and most or all of the phosphor settles on the substrate 100 and/or the upper surface of the LED chip 200, forming a phosphor sedimentation layer 320. Since the phosphor generates heat when excited, the phosphor sedimentation layer 320 settling on or near the substrate facilitates the dissipation of heat generated by the phosphor through the substrate. The upper part of the first encapsulant layer 300 is a relatively transparent layer 310, and the lower part is the phosphor sedimentation layer 320, which results in a high concentration of phosphor near the LED chip. This allows the light emitted by the LED chip to better excite the phosphor, improving excitation efficiency, and reducing the blocking of light by the phosphor when the light passes through the transparent layer 310.

In specific applications, as shown in 2a and 2b, the height of the phosphor adhesive (first encapsulant layer 300) is lower than the top surface of the dam part 110, and it can take the form of a concave cup with a depressed middle surface and protruding edges (as shown in FIG. 2b) or a semi-bowl structure with a flat surface and lower than the top surface of the dam part 110 (as shown in FIG. 2a). The purpose is to provide a carrying space for the subsequent process of forming the upper convex cup adhesive (i.e., the second encapsulant layer 420), so that even if there is a slight deviation in the dispensing of the second encapsulant layer 420, it can automatically flow into the empty space, preventing the second encapsulant layer 420 from overflowing outside the dam part 110. This reduces the difficulty of the production process, improves production yield, and increases the contact area between the second encapsulant layer 420 and the first encapsulant layer 300 and the dam part 110, enhancing the bonding force between different layers. To ensure that at least part or all of the phosphor settles, centrifugal equipment can be used to settle the phosphor after the semi-solid first encapsulant layer 300 is placed on the substrate, forming the phosphor sedimentation layer 320. Above the phosphor sedimentation layer 320 is the transparent layer. After the centrifugal process, a quick-bake process is used to bake the phosphor adhesive (first encapsulant layer 300). The quick-bake process includes baking at a low temperature of 43° C. for 30-40 minutes, followed by baking at 130-150° C. for 5-10 minutes, which can eliminate adhesive bubbles and slightly dry the adhesive surface.

In specific applications, as shown in FIG. 3b and FIG. 6b, the central part of the second encapsulant layer 420 is arched upward relative to the periphery, forming a spherical-like shape. The second encapsulant layer 420 can be formed through a dispensing process. The hollow particle aggregation area 410 is located at the spherical cap part of the top of the spherical shape. From the cross-sectional view in FIG. 3b, the hollow particle aggregation area 410 is crescent-shaped (thin at the edges, thick at the center, and with an arc-shaped bottom). Compared to the flat structure at the top (refer to FIG. 3a), in this embodiment, only the spherical cap part (central part) is provided with hollow particles. The hollow particles do not need to cover the flat structure, and the amount of hollow particles can be relatively small. In some application scenarios where the light intensity on the top surface of the LED needs to be ensured, this can reduce the obstruction of light in the middle part of the LED and minimize the loss of light intensity at the top of the LED light-emitting device. Moreover, by heating the second encapsulant layer 420, the hollow particles can be aggregated upward to the protruding upper end of the second encapsulant layer 420, forming the hollow particle aggregation area 410 directly above the LED chip 200 in the central top area, which is beneficial for manufacturing.

Specifically, as shown in FIG. 1, the width A of the top of the dam part 110 is not greater than 200 μm, and the height H1 of the dam part 110 is not greater than 450 μm. Limiting the height of the dam part 110 can increase the light mixing area and distance above the substrate 100, enhance the light emission angle and the light intensity on both sides, and reduce the obstruction of light by the dam part 110.

Specifically, as shown in FIG. 2a and FIG. 2b, the inner peripheral side of the dam part 110 is a vertical surface (refer to FIG. 2a) or an inwardly inclined surface (refer to FIG. 2b), and the outer peripheral side of the dam part 110 is a vertical surface (refer to FIG. 2a) or an outwardly inclined surface (refer to FIG. 2b). In the embodiment shown in FIG. 2b, the inclination angle of the inner side wall of the dam part 110 relative to the front surface of the substrate 100 can increase the contact area between the dam part and the encapsulant layer, enhancing the bonding force between the inner surface of the dam part 110 and the adhesive of the encapsulant layer. This can reduce the occurrence of adhesive overflow when using a larger amount of encapsulation adhesive, and the more encapsulation adhesive used, the better the light distribution effect.

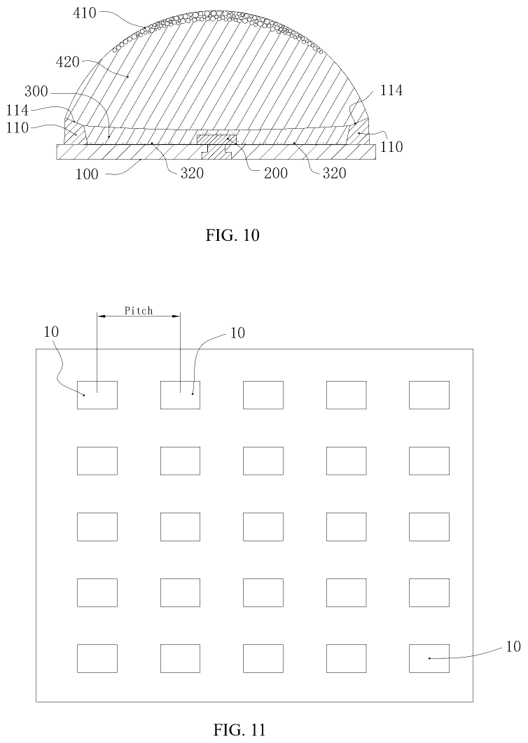

As shown in FIG. 2b and FIG. 10, the top surface of the dam part 110 can be a plane 112 parallel to the substrate plane (refer to FIG. 2b) or an inclined surface 114 that is not parallel to the substrate and tilts inward (refer to FIG. 10). In the embodiment shown in FIG. 10, the inward tilt of the top surface of the dam part 110 can increase the contact area between the dam part and the encapsulant layer. Enhancing the bonding force between the top surface of the dam part 110 and the gel of the encapsulant layer can reduce the occurrence of gel overflow when using a larger amount of encapsulant.

In another embodiment, as shown in FIG. 13, the cross-section of the dam part 110 is triangular, meaning the top surface of the dam part 110 is pointed, reducing the top thickness of the dam part 110 to increase light transmittance, improve light output on both sides, and reduce the material of the dam part 110. Additionally, the inclined area of the inner side surface 301 of the dam part 110 is larger, reflecting part of the light hitting the inner side surface 301 to the periphery of the LED light-emitting device and increasing the contact area between the encapsulant layer 400 and the dam part 110, thereby improving the bonding force and airtightness between the encapsulant layer 400 and the support 120.

Specifically, the first encapsulant (first encapsulant layer) 300 and the second encapsulant (second encapsulant layer) 420 use the same gel material, meaning the second encapsulant layer 420 is selected from the same manufacturer and the same type of gel as the first encapsulant layer 300 (fluorescent gel), resulting in good bonding effect. In this embodiment, the first encapsulant layer can be silicone, and the second encapsulant layer can also be silicone.

Specifically, the content (by mass) of the hollow particles in the second encapsulant layer 420 can be 1%-5%, which has a good effect.

Specifically, the median particle size of the hollow particles can be 15 μm-100 μm, where the median particle size, also known as the D50 particle size or median diameter, refers to the particle size value corresponding to a cumulative distribution percentage of 50%. This is a typical value representing particle size, accurately dividing the total population into two equal parts, meaning 50% of the particles have a size exceeding this value, and 50% have a size below this value. If a sample has a D50=5 μm, it means that among all the particles of different sizes in the sample, particles larger than 5 μm account for 50%, and particles smaller than 5 μm also account for 50%. In this embodiment, the median particle size of the hollow particles can be 40 μm, meaning hollow particles larger than 40 μm account for 50%, and hollow particles smaller than 40 μm also account for 50%.

Specifically, taking the LED lamp bead of model 2835 as an example, the overall height of the LED light-emitting device can be between 1.3 mm and 1.7 mm, the thickness of the hollow particles in the hollow particle aggregation area 410 can be 50-150 μm, the shape of the hollow particle aggregation area 410 can be approximately circular or elliptical, and its coverage diameter D can be 1800-2200 μm.

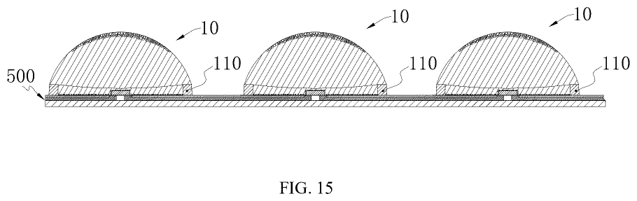

As shown in FIG. 15, in one embodiment, multiple LED light-emitting devices 10 can also share a single substrate 500. On the substrate 500, multiple dams 110 can be formed to create an LED light board or strip, and the substrate 500 can be a PCB board.

The present disclosure also provides a method for manufacturing an LED light-emitting device, used to manufacture the aforementioned LED light-emitting device, including the following steps:
preparing a side-light-transmitting support and providing an encapsulant layer with hollow particles on the support 120, where the hollow particles are transparent or translucent; and
allowing the height of the encapsulant layer protruding from the support 120 greater than the height of the support 120.

The hollow particles are white (transparent) particles with reflective and refractive properties, allowing the light directly above the lamp bead to be reflected and refracted by the hollow particles to the outside of the lamp bead and mixed with the external light for secondary light mixing, so that the light intensity in the middle of the lamp bead is appropriately reduced to increase the light intensity on both sides of the lamp bead; moreover, the hollow structure of the hollow particles has good light transmittance, thus improving the side light intensity without significantly reducing the overall brightness of the lamp bead, which enhances the light intensity in the areas between the chips when applied to the backlight board of a display screen, allowing for an increase in the pitch of the lamp beads on the board, reducing the number of lamp beads on the same board, lowering the cost of the lamp beads, resulting in a display product with excellent brightness, good light uniformity, effective experience, and low application cost. The height of the dam part 110 is the distance from the front of the substrate 100 to the top of the dam part 110, the height of the encapsulant layer 400 protruding from the support 120 is the distance from the top of the dam part 110 to the top of the encapsulant layer, and the height of the encapsulant layer 400 protruding from the support 120 is greater than the height of the dam part 110, which can reduce the proportion of the dam part 110 height in the total height of the LED light-emitting device, and when combined with the hollow particles set at the top of the encapsulant layer, it can increase the light output from the top and sides of the LED light-emitting device compared to the prior art, while also improving light uniformity, resulting in an effective experience of the LED light-emitting device.

Specifically, in one embodiment, preparing the support can include the following steps: preparing a substrate 100 and integrally forming or fixedly providing a dam part 110 in a closed shape on the substrate 100 to form a chip mounting area 130;
connecting the LED chip 200 to the substrate 100 and positioning the LED chip 200 inside the dam part 110 (i.e., within the chip mounting area 130).

In one embodiment, providing the encapsulant layer includes the following steps: placing a semi-solid first encapsulant containing phosphor (i.e., the first encapsulant layer 300) inside the dam part 110, and allowing at least part or all of the phosphor to settle on the surface of the substrate 100 and/or the LED chip 200. Specifically, the phosphor can be settled through a centrifugal process, and the first encapsulant layer 300 can be cured or semi-cured using a rapid baking process.

After the first encapsulant layer 300 is cured or preliminarily cured (i.e., semi-cured), a second encapsulant layer 420 mixed with hollow particles is placed above the first encapsulant layer 300, and heating is applied to allow at least part or all of the hollow particles to aggregate at the top of the second encapsulant layer 420, forming a hollow particle aggregation area 410.

In this embodiment, the hollow particles are glass microspheres with a hollow center, characterized by low density and light weight. After heating, they aggregate in the upper region of the encapsulant. The hollow particles are transparent or semi-transparent particles with a hollow structure, possessing reflective and refractive properties. This causes the light directly above the lamp bead to be reflected and refracted by the hollow particles, redirecting the central light intensity to the sides, thereby enhancing the light intensity on both sides of the lamp bead.

In one embodiment, the second encapsulant layer 420 is silicone. As shown in FIG. 7 of the prior art, a white adhesive 202 is used to cover the LED light-emitting device (referred to as the white adhesive product), resulting in significant light intensity loss above the LED light-emitting device. In this application, by selecting silicone combined with hollow particles above the lamp bead (LED light-emitting device), the hollow particles are suspended above the LED chip 200, protruding above the LED device, thereby improving brightness compared to the prior art white adhesive product. Additionally, the light transmittance of the silicone in this application is much higher than that of the transparent dam, therefore the luminous flux of the white adhesive product in the prior art is 30% lower than that of the product using hollow particles at the same color point. Therefore, the LED light-emitting device provided in this embodiment of the present disclosure enhances the light intensity on both sides, allowing for increased spacing (Pitch) between lamp beads on the light board, reducing the number of lamp beads on the same board, lowering the cost of the lamp beads, and providing excellent brightness and user experience for display products at a low application cost.

Specifically, according to the manufacturing method of this embodiment, the height of the first encapsulant layer 300 containing phosphor, which is set within the surrounding dam 110, is preferably lower than the top surface of the surrounding dam 110. This ensures that when the phosphor settles to the bottom through the centrifugal process, the first encapsulant layer 300 will not be thrown out of the surrounding dam 110, allowing the phosphor to cover the substrate 100 and the upper surface of the LED chip 200. Then, a rapid curing process can be used to cure the first encapsulant layer 300. The rapid curing process involves baking at 43° C. for 30-40 minutes, followed by baking at 130° 150° C. for 5-10 minutes.

After setting the second encapsulant layer 420 mixed with hollow particles above the first encapsulant layer 300, baking is performed to cause the hollow particles to aggregate at the top of the second encapsulant layer 420, forming a hollow particle aggregation area 410. The baking conditions are 43° C. for 20-30 minutes, then increasing the temperature to 100° C. for 10-30 minutes to release stress, followed by baking at 150° C. for 150-180 minutes to solidify.

According to the LED light-emitting device and the method for manufacturing the same provided by the embodiment of the present disclosure, the LED light-emitting device utilizes phosphor in combination with the LED chip, allowing the light emitted by the LED chip to mix with the light excited by the phosphor for wavelength conversion. Therefore, there is no need to use a quantum dot film. The light-emitting intensity of the LED light-emitting device provided by the embodiment of the present disclosure is higher than that in the prior art. In some application scenarios, it may not require or reduce the need for DBEF film (brightness enhancement film) for secondary brightness enhancement, offering advantages such as low cost, high brightness, and ultra-wide angle. Since hollow particles have the characteristics of low density and light weight, they aggregate in the upper region of the encapsulant after heating. Hollow particles have reflective and refractive properties, causing the light directly above the lamp bead to be reflected and refracted by the hollow particles, thereby refracting/reflecting the central light intensity of the lamp bead to the sides to enhance the light intensity on both sides of the lamp bead. Additionally, since hollow particles are transparent particles, they do not absorb the original light energy of the lamp bead, thus increasing the peripheral brightness of the lamp bead without significantly reducing its overall brightness.

The LED light-emitting device provided by the embodiments of the present disclosure has a large amount of light emitted from all sides, and the light-emitting effect is shown in 6b. In the prior art shown in FIG. 7, the phosphor glue 201 of the LED light-emitting device 20 is covered with white adhesive 202, which significantly blocks light, allowing only a small portion of light to be emitted from the top of the LED light-emitting device 20. The light transmission effect of the dam 203 is not as good as that of silicone, therefore the light emitted from the sides of the dam 203 is less, resulting in a poor light-emitting effect. FIG. 8 shows the light intensity distribution of the LED light-emitting device provided in this embodiment, and FIG. 9 shows the light intensity distribution of the white glue product in the prior art. The horizontal axis represents the light-emitting angle, and the vertical axis represents the light intensity (unit: cd, candela). From the light intensity distribution in FIGS. 8 and 9, it can be seen that the light intensity distribution of the fully covered white glue product in FIG. 9 has a low side light intensity (maximum value less than 1.6). The light intensity distribution curve in FIG. 8 is slightly concave in the middle, with the maximum light intensity distributed on both sides of the normal line, and the extreme value of light intensity can reach more than 1.8, which can improve the uniformity of brightness. When increasing the spacing between LEDs, the uniformity of brightness can also be ensured to meet the specifications required by customers, thereby reducing the number of LEDs used to lower application costs, with good application effects. When designing a Mini POB backlight module, the number of lamp beads can be reduced, as shown in FIG. 12. The ratio of OD (Optimal Distance, which is the distance from the LED to the irradiation surface; in direct-lit backlight modules, OD is the distance between the diffusion plate and the upper surface of the PCB) to PITCH (lamp bead spacing) can be increased to 1:1.6, with low application costs.

The above description is only the preferred embodiment of the present disclosure and is not intended to limit the present disclosure. Any modifications, equivalent replacements, or improvements made within the spirit and principles of the present disclosure should be included within the protection scope of the present disclosure.

1. An LED light-emitting device, comprising:
a support, comprising a substrate having opposite front and back surfaces and a dam part disposed on the front surface of the substrate and having opposite bottom and top surfaces,
an LED chip disposed on the front surface of the substrate and located within an area enclosed by the dam part; and
an encapsulant layer disposed above the LED chip and filling a chip mounting area enclosed by the dam part for encapsulating the LED chip;
wherein the chip mounting area is circular or rectangular in a top view, and the dam part has a square outer contour in the top view;
a top of the encapsulant layer is provided with transparent or translucent hollow particles;
both the dam part and the encapsulant layer are made of transparent or translucent materials;
a height (H1) of the dam part is a distance from the front surface of the substrate to a top surface of the dam part, and a protruding height (H2) of the encapsulant layer is a distance from the top surface of the dam part to a top of the encapsulant layer, wherein the protruding height (H2) of the encapsulant layer is greater than the height (H1) of the dam part, and the protruding height (H2) ranges from 1 to 2 times a value of the height (H1); and
the dam part has a length (H4) and a width (H5), and the protruding height (H2) of the encapsulant layer is less than the length (H4) and width (H5) of the dam part to prevent overflow of the encapsulant layer during a manufacturing process.

2. The LED light-emitting device according to claim 1, wherein an outer surface of the encapsulant layer is curved and has a shape that is larger at a bottom and smaller at a top; and the top of the encapsulant layer is located directly above the chip mounting area, and the hollow particles cover an area directly above the LED light-emitting device.

3. The LED light-emitting device according to claim 1, wherein at least part of the encapsulant layer is not covered by the hollow particles, and the hollow particles at least cover an area directly above the LED chip.

4. The LED light-emitting device according to claim 2, wherein a projection area of the hollow particles on a bottom surface of the encapsulant layer accounts for 20%-80% of a bottom surface area of the encapsulant layer.

5. The LED light-emitting device according to claim 1, wherein the encapsulant layer comprises a first encapsulant layer and a second encapsulant layer, wherein a bottom of the first encapsulant layer is encapsulated on the front surface of the substrate, and a bottom of the second encapsulant layer is encapsulated on a top of the first encapsulant layer; and the first encapsulant layer contains phosphor, and most of the phosphor is located at the bottom of the first encapsulant layer; and a top surface of the first encapsulant layer is lower than a top surface of the dam part.

6. The LED light-emitting device according to claim 5, wherein a mass content of the hollow particles in the second encapsulant layer is 1%-5%.

7. The LED light-emitting device according to claim 6, wherein a median particle size of the hollow particles is 15 μm-100 μm.

8. The LED light-emitting device according to claim 1, wherein the top surface of the dam part is inclined toward an inner side of the dam part.

9. A method for manufacturing an LED light-emitting device for manufacturing the LED light-emitting device according to claim 1, comprising the following steps of:
preparing a support comprising a dam part and providing an encapsulant layer with hollow particles on the support, the encapsulant layer comprising a first encapsulant containing phosphor and a second encapsulant;
wherein after providing the first encapsulant within the dam part, the phosphor is settled by a centrifugal process, and the first encapsulant is cured or semi-cured by a quick-bake process;
wherein the second encapsulant mixed with the hollow particles is provided above the first encapsulant, and the hollow particles are allowed to aggregate at a top of the second encapsulant by baking to form a hollow particle aggregation area; and
allowing a height of the encapsulant layer protruding from the support greater than a height of the support.

10. (canceled)

11. The LED light-emitting device according to claim 1, wherein the encapsulant layer is dome-shaped or has a tapered structure that is wider at a bottom and narrower at a top, with the top thereof located directly above the chip mounting area.

12. The LED light-emitting device according to claim 2, wherein a thickness of the encapsulant layer not covered by the hollow particles is at least greater than the height of the dam part.

13. The method for manufacturing an LED light-emitting device according to claim 9, wherein an outer surface of the encapsulant layer is curved and has a shape that is larger at a bottom and smaller at a top; and a top of the encapsulant layer is located directly above a chip mounting area, and the hollow particles cover an area directly above the LED light-emitting device.

14. The method for manufacturing an LED light-emitting device according to claim 9, wherein at least part of the encapsulant layer is not covered by the hollow particles, and the hollow particles at least cover an area directly above an LED chip.

15. The method for manufacturing an LED light-emitting device according to claim 14, wherein a projection area of the hollow particles on a bottom surface of the encapsulant layer accounts for 20%-80% of a bottom surface area of the encapsulant layer.

16. The method for manufacturing an LED light-emitting device according to claim 9, wherein a top surface of the first encapsulant layer is lower than a top surface of a dam part of the support.

17. The method for manufacturing an LED light-emitting device according to claim 16, wherein a mass content of the hollow particles in the second encapsulant layer is 1%-5%.

18. The method for manufacturing an LED light-emitting device according to claim 17, wherein a median particle size of the hollow particles is 15 μm-100 μm.

19. The method for manufacturing an LED light-emitting device according to claim 9, wherein a top surface of a dam part of the support is inclined toward an inner side of the dam part.

20. The method for manufacturing an LED light-emitting device according to claim 9, wherein the encapsulant layer is dome-shaped or has a tapered structure that is wider at a bottom and narrower at a top, with the top thereof located directly above a chip mounting area.

21. The method for manufacturing an LED light-emitting device according to claim 13, wherein a thickness (H3) of the encapsulant layer not covered by the hollow particles is at least greater than the height (H1) of a dam part of the support.
